(19) United States
(12) Patent Application Publication
(10) Pub. No.: US 2021/0328559 A1
(43) Pub. Date: Oct. 21, 2021

(54) SYSTEMS WITH ADC CIRCUITRY AND ASSOCIATED METHODS

(71) Applicant: SEMICONDUCTOR COMPONENTS INDUSTRIES, LLC, Phoenix, AZ (US)

(72) Inventor: Bharat BALAR, Bengaluru (IN)

(73) Assignee: SEMICONDUCTOR COMPONENTS INDUSTRIES, LLC, Phoenix, AZ (US)

(21) Appl. No.: 16/948,274

(22) Filed: Sep. 10, 2020

(30) Foreign Application Priority Data
Apr. 16, 2020 (IN) 202011016463

(51) Int. Cl. H03F 3/193; H03F 1/02; G01S 13/04; G01S 7/03

(52) U.S. Cl. CPC H03F 3/193; H03F 1/0205; H03F 2200/451; G01S 7/032; G01S 13/04

(57) ABSTRACT

Systems with object detection capabilities may include a radio detection and ranging (RADAR) system. The RADAR system or other portions of the systems may include analog-to-digital converter circuitry. The analog-to-digital converter circuitry may be implemented as pipeline analog-to-digital converter circuitry having multiple stages. Each stage may include multiplying digital-to-analog converter circuitry having a sampling network and amplifier circuitry. The amplifier circuitry may be implemented as a two-stage amplifier. One or more transistors in the two-stage amplifier may receive adaptive control signals that counteract bias current changes across the one or more transistors due to supply voltage changes.

This application claims the benefit of and claims priority to Indian Patent Application No. 202011016463, filed Apr. 16, 2020, which is hereby incorporated by reference herein in its entirety.

### BACKGROUND

This relates generally to amplifier circuitry and analog-to-digital converter (ADC) circuitry, and more specifically, to radio detection and ranging (RADAR) systems having ADC circuitry with amplifier circuitry, and to the associated methods. Modern object detection systems can use RADAR systems to detect range, angle, and velocity of objects. These systems can include corresponding circuits operating in an analog domain or a digital domain. To bridge communications between the two domains, these systems can include analog-to-digital converter circuitry. In particular, a RADAR system can include receiver circuitry that uses ADC circuitry such as a pipeline ADC for medium/high speed and resolution applications in converting analog signals to digital data.

Pipeline ADCs typically include multiplying digital-to-analog converter (MDAC) stages. It can be difficult to design MDAC stages with minimized power consumption while providing satisfactory performance. As an example, amplifier circuitry in the MDAC stages can include transistors. In some applications such as those that require high-speed circuit designs, it may be desirable to use transistors with shorter channel lengths. However, because these transistors have shorter channel lengths, bias current can start increasing with channel length modulation effects. This can lead to an undesirable increase in power consumption for these circuits.

It would therefore be desirable to provide systems having improved amplifier circuitry, especially improved amplifier circuitry in MDAC stages for pipeline ADCs, with reduced power consumption and satisfactory performance.

### BRIEF DESCRIPTION OF THE DRAWINGS

FIG. 1 is a diagram of an illustrative electronic system having a RADAR system in accordance with some embodiments.

FIG. 2 is a diagram of illustrative receiver chain circuitry for processing received antenna signals in accordance with some embodiments.

FIG. 3 is a diagram of illustrative pipeline ADC circuitry in accordance with some embodiments.

FIG. 4 is a diagram of illustrative two-stage amplifier circuitry for ADC circuitry such as the ADC circuitry shown in FIG. 3 in accordance some embodiments.

FIG. 5 is a diagram of an illustrative control signal generation circuit in accordance with some embodiments.

FIG. 6 is a diagram of an illustrative control signal generation circuit that is adaptive in accordance with some embodiments.

### DETAILED DESCRIPTION

Embodiments of the present invention relate to systems with amplifier circuitry and/or ADC circuitry, and more particularly to a two-stage MDAC operational transconductance amplifier (OTA) design for a pipeline ADC having control signals generated by adaptive control signal generation circuitry. If desired, the systems and methods in the present embodiments may be implemented in any suitable system such as a RADAR system. It will be recognized by one skilled in the art, that the present exemplary embodiments may be practiced without some or all of these specific details. In other instances, well-known operations have not been described in detail in order not to unnecessarily obscure the present embodiments.

The amplifier circuitry (e.g., OTA circuitry), the MDAC circuitry (e.g., MDAC stages having respective sampling networks), and the ADC circuitry (e.g., pipeline ADC circuitry) described herein may be generally implemented to perform bias current balancing such as to perform bias current balancing for transistors in a second stage of a two-stage MDAC OTA for a pipeline ADC.

As examples, the amplifier, MDAC, and ADC circuitry, and the associated systems and methods described herein may be implemented, separately or in combination, as part of any electronic device such as a portable electronic device, a camera, a tablet computer, a desktop computers, a webcam, a cellular telephone, a video camera, a video surveillance system, an automotive imaging system, a video gaming system, a RADAR system, or any other electronic device that may include or exclude imaging capabilities. The amplifier circuitry, MDAC circuitry, and ADC circuitry, and associated systems and methods being implemented as part of a RADAR system or an electronic system having object detection capabilities is described in detail herein as an example. However, this particular example is merely illustrative. If desired, the amplifier, MDAC, and ADC circuitry, and the associated systems and methods may be implemented in any of the above-mentioned systems or any other suitable systems.

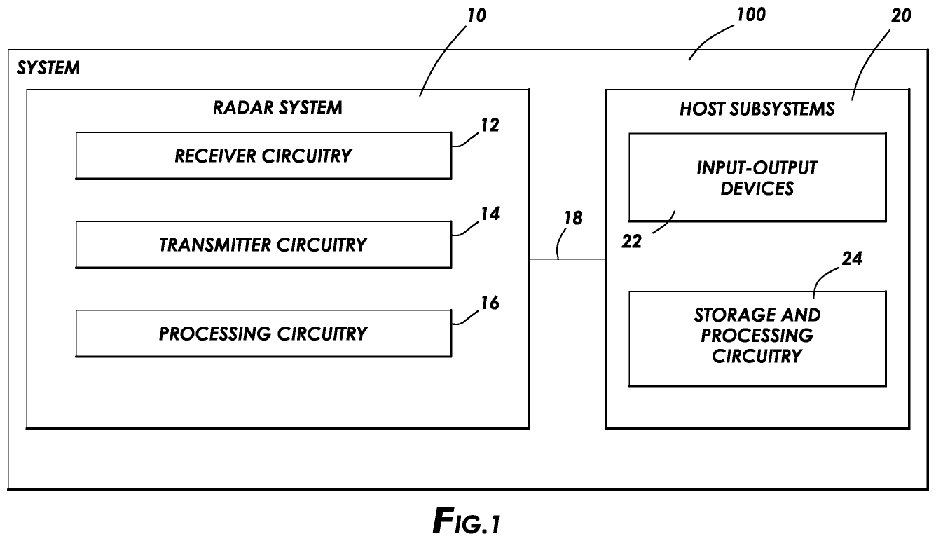

FIG. 1 is a diagram of an illustrative electronic system including a radio detection and ranging (RADAR) system that uses radio waves to perform object detection (e.g., by determining the range, angle, velocity, or other characteristics of objects in an environment). System 100 of FIG. 1 may be an electronic device such as a camera, a cellular telephone, a video camera, or other electronic device that captures digital image data, may be a vehicle safety system (e.g., an active braking system or other vehicle safety system), may be an object detection system (e.g., a RADAR-based system), may be a surveillance system, or may be any other suitable system.

As shown in FIG. 1, system 100 may include a RADAR system such as RADAR system 10 and host subsystems such as host subsystem 20. RADAR system 10 may include receiver circuitry 12, transmitter circuitry 14, and processing circuitry 16. Processing circuitry 16 may include baseband circuitry, signal generation circuitry, signal processing circuitry, or other types of circuitry (e.g., other types of circuitry for supporting the transmission and reception of antenna signals using receiver circuitry 12 and transmitter circuitry 14, other types of circuitry for supporting object detection operations, etc.).

Processing circuitry 16 may provide signals over transmitting signal paths to transmitter circuitry 14 for transmitting the signals (e.g., radio-frequency antenna signals) over antennas. Processing circuitry 16 may also receive signals over receiving signal paths from receiver circuitry 16 for receiving the signals using antennas. Based on the transmitted signals and the received signals the processing circuitry 16 may perform object detection operations (e.g., RADAR-based operations) and generate the corresponding data for further processing and/or storage.

RADAR system 10 (e.g., processing circuitry 16) may convey generated data to host subsystem 20 over path 18. Host subsystem 20 may include processing software instructions for further identifying or detecting objects in the environment, for detecting motion of objects relative to other objects, for determining distances to objects, for filtering or otherwise processing the generated data provided by RADAR system 10.

If desired, system 100 may provide a user with numerous high-level functions. In a computer or advanced automotive system, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

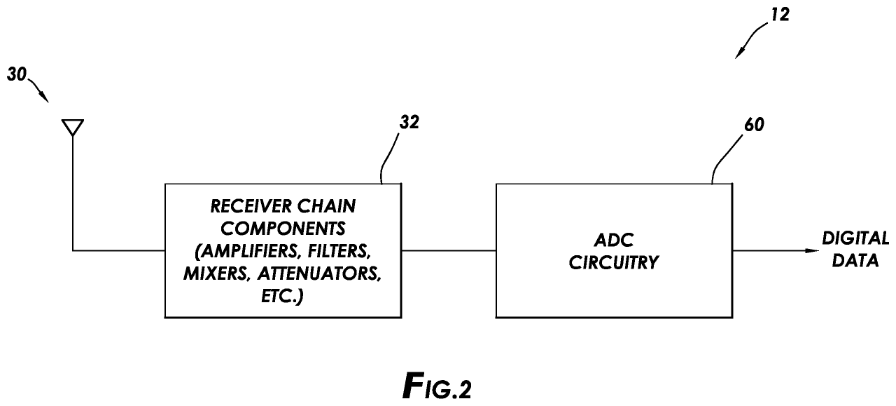

FIG. 2 is a diagram of circuitry on a receiver chain path for receiver circuitry such as receiver circuitry 12 in FIG. 1. In particular, receiver circuitry 12 may include antenna circuitry 30 (e.g., one or more antennas having antenna resonating elements, antenna tuning elements, etc.). Antenna circuitry 30 may be coupled to processing circuitry (e.g., a baseband processor of processing circuitry in FIG. 1) via one or more receiver chain path.

Receiver chain components such as receiver chain components 32 may be interposed along the receiver chain path. In particular, receiver chain components may include amplifier circuitry, filter circuitry, mixer circuitry, attenuator circuitry, and other types of signal processing circuitry.

As a particular example, the radio-frequency signals received by antenna circuitry 30 may pass through a low-noise amplifier, and subsequently, a mixer. The mixer may down-convert the frequency of the received signal to generate a corresponding signal having an intermediate frequency. The signal having the intermediate frequency may thereafter pass through a series of filters (e.g., high-pass filters, low-pass filters, and/or band-pass filters) and amplifiers to remove any undesired noise and improve signal quality. This is merely illustrative. If desired, other suitable operations may be performed on the signal received by antenna circuitry 30. The final processed antenna signal may be output from receiver chain components 32 (e.g., a last component in the series of receiver chain components) to downstream circuitry.

To convert analog antenna-based signals such as antenna signals after passing through receiver chain components 32, receiver circuitry 12 (e.g., the receiver chain path in receiver circuitry 12) may include ADC circuitry such as ADC circuitry 60. ADC circuitry 60 may generate digital data based on the analog signals and may provide the digital data to processing circuitry 16 (FIG. 1) for further processing and/or analysis. If desired, ADC circuitry 60 may also be included in any other suitable portion of system 100 in FIG. 1 (e.g., may be included in other portions of RADAR system 10 and/or in host subsystems 20 in FIG. 1).

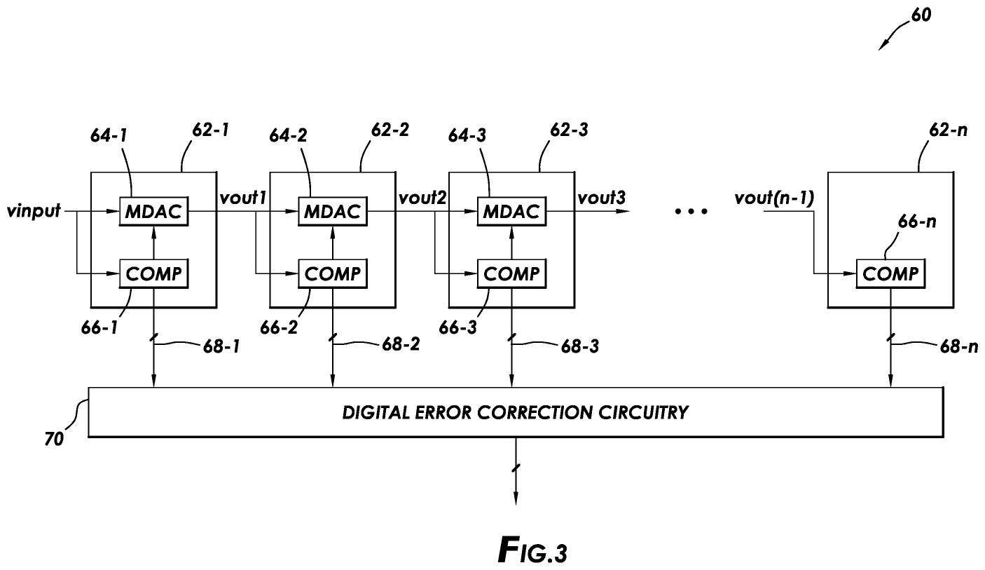

FIG. 3 is a block diagram of illustrative ADC circuitry such as ADC circuitry 60 in FIG. 2. As an example, ADC circuitry 60 may be implemented as pipeline ADC circuitry having multiple stages. As shown in FIG. 3, ADC circuitry 60 may include n stages 62-1, 62-2, 62-3, . . . , 62-n. Each stage 62, with the exception of the last stage 62-n, may include corresponding MDAC circuitry 64 and comparator circuitry 66, while the last stage 62-n may include comparator circuitry 66-n but may omit the corresponding MDAC circuitry 64 (or may have unused MDAC circuitry). Each corresponding MDAC circuitry 64 in stages 62 may pass signals to a subsequent stage, thereby creating a pipeline path. Stages 62 may therefore sometimes be referred to herein as MDAC stages 62.

ADC circuitry 60 may include any suitable number of MDAC stages 62. Stages 62 may perform conversion operations to resolve corresponding sets of bits (e.g., one bit, one-and-a-half bits, two bits, two-and-a-half bits, etc.), the combination of which are used to generate the final digital data.

In particular, MDAC circuitry 64-1 and comparator circuitry 66-1 in first stage 62-1 may receive an analog input signal vinput. Comparator 66-1 may resolve a first set of bits such as a set of most significant bits (e.g., a single bit, one-and-a-half bits, two bits, two-and-a-half bits, three bits, more than three bits, etc.). The first set of bits may include a portion of fully resolved bits and a portion of partially resolved bits (e.g., an overlap bit). Comparator 66-1 may provide the resolved first set of bits over path 68-1. Comparator 66-1 may also provide the resolved first set of bits to MDAC circuitry 64-1. MDAC circuitry 64-1 may convert the resolved first set of bits to an analog-equivalent signal and subtract the analog-equivalent signal associated with the first set of bits from the input analog signal vinput. The difference signal (e.g., between the analog-equivalent signal and the input analog signal vinput) may be amplified and provided to the next stage (e.g., stage 62-2) as signal vout1.

Based on input signal vout1, comparator circuitry 66-2 in stage 62-2 may generate a second set of bits that are output over path 68-2. MDAC circuitry 64-2 may convert the second set of bits to an analog-equivalent signal and subtract the analog-equivalent signal associated with the second set of bits form the input signal of stage 62-2 (e.g., signal vout1). The difference signal (e.g., between the analog-equivalent signal and the input signal of stage 62-2 vout1) may be amplified and provided to the next stage (e.g., stage 63-3) as signal vout2. In a similar manner, stage 62-3, 62-4, . . . , 62-n may output corresponding sets of bits over corresponding paths 68 and send corresponding output analog signal to the immediately subsequent stage if not the last stage (e.g., stage 62-n may output a corresponding set of bits such as the least significant bits over path 68-n but may omit passing an analog signal for a subsequent stage).

ADC circuitry 60 may include digital error correction circuitry 70. Digital error correction circuitry 70 may receive corresponding sets of bits resolved by stages 62 over paths 68. Digital error correction circuitry 70 generate the converted final digital data based on the received sets of bits (e.g., by resolving overlapping bits between different stages or by performing any other suitable processing operations).

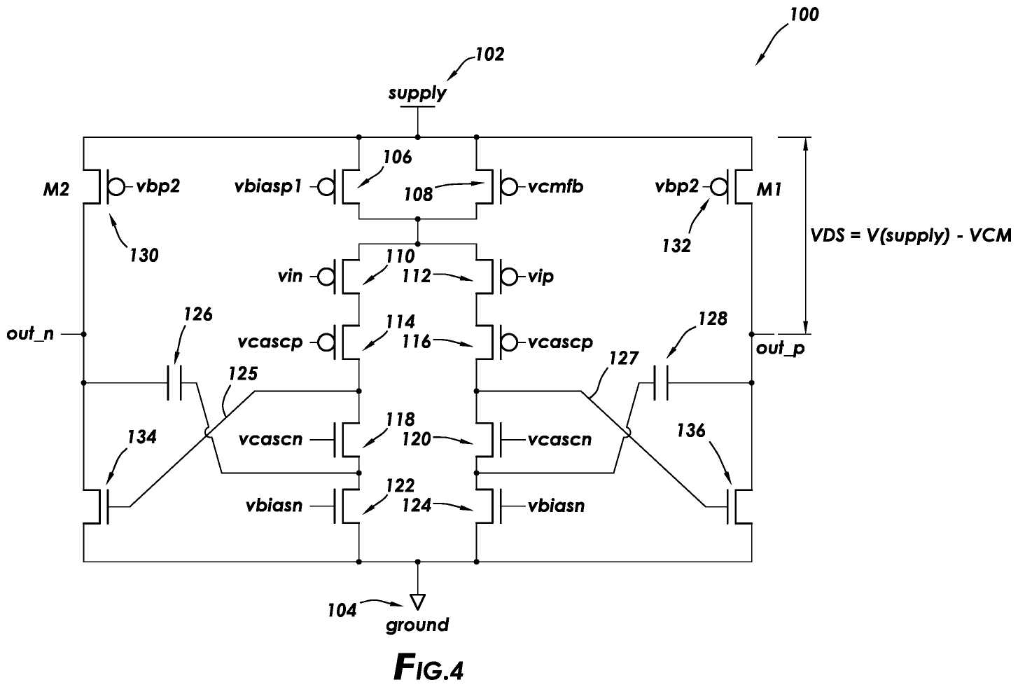

As described in connection with FIG. 3, MDAC circuitry 64 for each stage 62 in ADC circuitry 60 may include amplifier circuitry. FIG. 4 is a circuit diagram of illustrative amplifier circuitry that may be implemented in MDAC circuitry for one or more stages of ADC circuitry such as one or more of MDC circuitry 64 of ADC circuitry 60 in FIG. 3.

As shown in FIG. 4, amplifier circuitry 100 may be implemented as a two-stage operational transconductance amplifier (OTA). In particular, amplifier circuitry 100 may include a first set of transistors (e.g., transistors 106, 108, 110, 112, 114, 116, 118, 120, 122, and 124) that form a first amplifier stage of amplifier circuitry 100. Transistors 110 and 112 may be configured to receive input signals yin and vip (e.g., a differential signal pair to be amplified by amplifier circuitry 100), respectively. As an example, input signals yin and vip may be a differential input pair connected to output terminals of a sampling network within the same MDAC circuitry (MDAC circuitry 64 in FIG. 3) for the same MDAC stage, in which amplifier circuitry 100 is implemented. Signals yin and vip may be referred to herein as a differential input pair for amplifier circuitry 100.

Transistors 106 and 108 may be coupled in parallel relative to each other between power supply voltage terminal 102 and the shared source-drain terminals of transistors 110 and 112. Each of transistors 106 and 108 may couple power supply voltage terminal 102 providing a supply voltage to both transistors 110 and 112 (e.g., to the shared source-drain terminals of transistors 110 and 112). A source-drain terminal described herein refers to one of a source terminal or a drain terminal.

Transistor 106 may be a supply bias current transistor configured to receive control signal vbiasp1 at its gate terminal to supply a bias current using power supply voltage terminal 102. Transistor 108 may be a common mode feedback transistor (implementing a portion of a common mode feedback circuit). As such, transistor 108 may be configured to receive control signal vcmfb (e.g., a control signal from a common mode control circuit forming a feedback path coupled to differential outputs of amplifier circuitry 100) at its gate terminal.

Transistors 110 and 112 may receive as control signals, at respective gate terminals, signals yin and vip (e.g., a differential input pair from a differential output pair at the output terminals of a corresponding sampling network in a corresponding MDAC stage). Transistor 114 may be coupled in series with (e.g., share only one source-drain terminal with) transistor 110, and separately, transistor 116 may be coupled in series with transistor 112. Transistors 114 and 116 may receive as control signals, at respective gate terminals, the same signal vcascp. Transistors 114 and 116 may implement two corresponding cascodes (e.g., a corresponding cascode device) and may enable the first stage amplification for differential inputs yin and vip at the supply voltage terminal side.

At the ground voltage terminal side, transistors 118 and 122 may be coupled in series between transistors for one of the differential inputs (e.g., transistors 110 and 114 for signal yin) and power supply voltage terminal 104 providing a ground voltage, and more specifically, in series between transistor 114 and power supply voltage terminal 104. Transistors 120 and 124 may be coupled in series between transistors for the other one of the differential inputs (e.g., transistors 112 and 116 for signal vip) and power supply voltage terminal 104, and more specifically, in series between transistor 116 and power supply voltage terminal 104.

Transistors 122 and 124 may receive the same control signal vbiasn at their respective gate terminals and may supply corresponding bias currents using power supply voltage terminal 102 along respectively paths. Transistors 118 and 120 may receive the same control signal vcascn at their respective gate terminals. Transistor 118 and 120 may implement two corresponding cascodes (e.g., a corresponding cascode device) and may enable the first stage amplification for differential inputs yin and vip at the ground voltage terminal side.

Additionally, amplifier circuitry 100 may include a second set of transistors (transistors 130, 132, 134, and 136) that form a second amplifier stage of amplifier circuitry 100. Amplifier circuitry 100 may include transistors 130 and 134 coupled in series along a first path between power supply voltage terminal 102 providing a supply voltage and power supply voltage terminal 104 supplying a ground voltage. Transistors 132 and 136 may be coupled in series along a second path between power supply voltage terminal 102 and power supply voltage terminal 104. Output terminals of amplifier circuitry 100 for generating differential output signals out_n and out_p may be provided between transistors 130 and 134 along the first path, and between transistors 132 and 136 along the second path, respectively.

Paths 125 and 127 may couple the first stage of amplifier circuitry 100 to the second stage of amplifier circuitry 100. In particular, path 125 may couple the shared source-drain terminals between transistors 114 and 118 to a gate terminal of transistor 134. Similarly, path 127 may couple the shared source-drain terminals between transistors 116 and 120 to a gate terminal of transistor 136.

Capacitors 126 and 128 may also couple the first stage of amplifier circuitry 110 to the second stage of amplifier circuitry 100. In particular, capacitor 126 may couple the shared source-drain terminals of transistors 118 and 122 to the shared source-drain terminals of transistors 130 and 134 (supplying amplifier output signal out_n). Similarly, capacitor 128 may couple the shared source-drain terminals of transistors 120 and 124 to the shared source-drain terminals of transistors 132 and 136 (supplying amplifier output signal out_p).

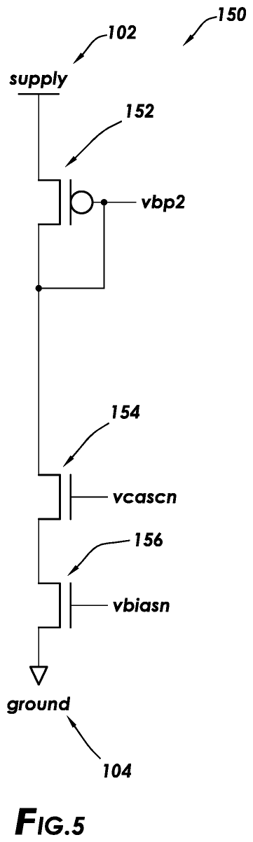

In the example of FIG. 5, transistors 106, 108, 110, 112, 114, 116, 130, and 132 may be PMOS transistors (p-type metal-oxide-semiconductor transistors), and transistors 118, 120, 122, 124, 134, and 136 may be NMOS transistors (n-type metal-oxide-semiconductor transistors). However, this example is merely illustrative. If desired, the types of transistors in amplifier circuitry 100 may be switched or implemented in any other suitable manner. Control signals and other configurations for these switched or changed transistor may be changed accordingly.

As show in FIG. 4, transistors 130 (M2) and 132 (M1) in the second stage of amplifier circuitry 110 may receive the same control signal vbp2 at their respective gate terminals. FIG. 5 is a circuit diagram that shows an illustrative control signal generation circuit for generating a control signal such as control signal vbp2 for transistors 130 and 132 in FIG. 4.

As shown in FIG. 5, control signal generation circuit 150 may include transistors 152, 154, and 156 couples in series between power supply voltage terminal 102 providing a supply voltage and power supply voltage terminal 104 providing a ground voltage. In the example of FIG. 5, transistor 152 may be an PMOS transistor, while transistors 154 and 156 may be NMOS transistors.

Transistor 152 may have a first source-drain terminal coupled to power supply voltage terminal 102 and a second source-drain terminal coupled to transistor 154. The second source-drain terminal of transistor 152 may also be coupled to the gate terminal of transistor 152 supplying control signal vbp2. Control signal vbp2 supplied by transistor 152 may be connected to and may control transistors 130 and 132 in FIG. 4 (and other transistors in other MDAC stages having corresponding two-stage MDAC OTAs).

However, referring back to FIG. 4, transistor 132 is coupled between supply terminal 102 and the corresponding output terminal of amplifier circuitry 100 (e.g., output terminal supplying signal out_p). In other words, transistor 132 may have a first source-drain terminal (e.g., a drain terminal) connected to voltage terminal 102 and may have a second source-drain terminal (e.g., a source terminal) connected to the corresponding output terminal of amplifier circuitry 100. A common mode voltage (when supplied at the output terminal of amplifier circuitry) is half of a reference voltage, and may be independent of a supply voltage supplied at power supply voltage terminal 102. As such, when the supply voltage increased (e.g., for high swing, high speed applications), the drain-source voltage VDS may increase (e.g., by virtue of the supply voltage V (supply) increasing while common mode voltage VCM remaining constant).

The increase in drain-source voltage VDS may undesirably reduce the effective channel length of the transistor (e.g., induce undesirable channel length modulation), and consequently, unnecessarily increases bias current and power consumption in the second-stage of amplifier circuitry 100. While described in connection with transistor 132, similarly effects may occur in connection with transistor 130 and other transistors in other amplifier circuitry for other MDAC stages. To reduce power consumption (and to reduce parasitic effects on the output nodes), it may be desirable to reduce channel modulation (e.g., mitigate channel shortening effects). While cascodes may be used in the second amplifier stage, the cascodes may limit the signal swing and may consequently limit maximum achievable signal-to-noise ratio (SNR).

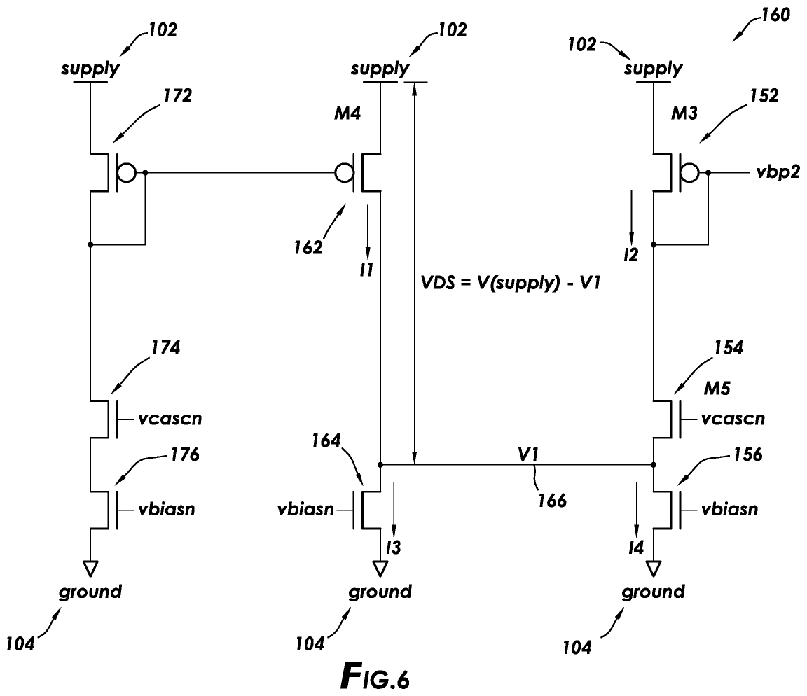

FIG. 6 is a diagram of a control signal generation circuit for adaptively generating a control signal such as control signal vbp2 for transistors 130 and 132 in FIG. 4 to reduce bias current and reduce power consumption. As shown in FIG. 6, control signal generation circuit 160 may include transistors 152 (M3), 154 (M5), and 156 couples in series between power supply voltage terminal 102 providing a supply voltage and power supply voltage terminal 104 providing a ground voltage. Transistor 152 may have a first source-drain terminal coupled to power supply voltage terminal 102 and a second source-drain terminal coupled to transistor 154. The second source-drain terminal of transistor 152 may also be coupled to the gate terminal of transistor 152 supplying control signal vbp2. Control signal vbp2 supplied by transistor 152 may be connected to and may control transistors 130 and 132 in FIG. 4 (and other transistors in other MDAC stages having corresponding two-stage MDAC OTAs in the same bias current block).

Additionally, control signal generation circuit 160 may include an adaptive portion (e.g., an adaptive circuit) configured to mimic the bias current change due to any supply voltage changes in the supply voltage at terminals 102. The adaptive circuit may also be configured to counterbalance the bias current changes through transistors in the second amplifier stage (e.g., transistors 130 and 132 in FIG. 4), thereby reducing unnecessary power consumption. In other words, power consumption is kept independent of the supply voltage.

In particular, the adaptive portion of signal generation circuit 160 may include transistors 162 (M4) and 164 coupled in series between power supply terminals 102 and 104 along a separate path than the path along which transistors 152, 154, and 156 are coupled. The adaptive portion of signal generation circuit 160 may include transistors 172, 174, and 176 coupled in series between power supply terminals 102 and 104 along a third separate path.

Transistors 172, 174, and 176 may be in a similar configuration as signal generation circuit 150 in FIG. 5 (e.g., as transistors 152, 154, and 156 in FIG. 5 or 6). As such, transistors 172, 174, and 176 may mimic the generation of a mimicked control signal for transistors in the second amplifier stage (e.g., transistors 130 and 132 in FIG. 4) without adaptive effects or inducing channel length modulation. The mimicked control signal may be supplied to transistor 162 at its gate terminal. Accordingly, transistor 162 may supply a bias current I1 based on the mimicked control signal generated by transistor 172. As such, any supply voltage change may be similarly change bias current I1.

In particular, transistor 162 may have a first source-drain terminal (e.g., a drain terminal) connected to terminal 102 and a second source-drain terminal (e.g., a source terminal) connected to path 166. Path 166 may be kept at a constant voltage V1 (even with changing supply voltage) because voltage V1, which is equal to the gate-source voltage VGS of transistor 154 subtracted from voltage vcascn, is independent of any supply voltage changes. Because drain-source voltage VDS of transistor 162 may be the difference between V (supply) at terminal 102 and voltage V1 at path 166 (which may be constant), transistor 162 may mimic (e.g., replicate or mirror) channel length modulation effects similar to those experienced by transistors 130 and 132 in FIG. 4.

Transistor 164 may receive, at its gate terminal, the same control signal vbiasn as the control signal received by transistor 156. Transistors 164 and 156 may each have a corresponding first source-drain terminal coupled to terminal 104 and a corresponding second source-drain terminal coupled to path 166. Transistor 164 may generate bias current I3 generated by transistor 164. Similarly, transistor 156 may generate bias current I4. Transistors 152, 162, and 172 may be PMOS transistors, while transistors 154, 156, 164, 174, and 176 may be NMOS transistors.

Based on the configuration of signal generation circuit 160, the sum of currents I1 and 12 may be equal to the sum of currents I3 and I4. Additionally, the sum of currents I3 and I4 may be independent of changes in the supply voltage (e.g., may be constant with changing supply voltage). Given these factors, any changes in current I1 may generate a corresponding inverted change in current I2, thereby providing an adapted control signal vbp2 (e.g., to transistors 130 and 132 in FIG. 4) to reduce bias current and power consumption.

As a particular example, when supply voltage (e.g., at terminal 102) increases by a given amount, current I1 may change by a corresponding amount due to a change in drain-source voltage VDS of transistor 162. Because the sum of currents I1 and 12 may be equal to the sum of currents I3 and I4 and the sum of currents I3 and I4 remains constant, current I2 may be reduced by the inverted version of the corresponding amount. This reduction may provide a control signal vbp2 to transistors such as transistors 130 and 132 in FIG. 4 to counteract (or reduce) any increase in bias current at these transistors (due to the increase in supply voltage), thereby keeping power consumption independent of supply voltage change.

Various embodiments have been described illustrating adaptive control signal generation circuitry for adaptively generating control signals for transistors based on changes in supply voltage.

As an example, amplifier circuitry may include: a first amplifier stage having a pair of input terminals for the amplifier circuitry; a second amplifier stage having a pair of output terminals for the amplifier circuitry and a transistor having a gate terminal; a first power supply voltage terminal; a second power supply voltage terminal; and a control signal generation circuit coupled to the gate terminal of the transistor, the control signal generation circuit having a first set of transistors that is between the first and second power supply voltage terminals and that is coupled to the gate terminal of the transistor, and the control signal generation circuit having a second set of transistors that is between the first and second power voltage terminals and that is coupled to the first set of transistors. The transistor may be interposed between the second power supply voltage terminal and a given output terminal in the pair of output terminals.

If desired, the first set of transistors may include a first additional transistor having a gate terminal coupled to the gate terminal of the transistor in the second amplifier stage. The first set of transistors may include a second additional transistor coupled in series with the first additional transistor between the first and second power supply voltage terminals. The second set of transistors may include a third additional transistor configured to mimic the transistor in the second amplifier stage. The second set of transistors may include a fourth additional transistor coupled in series with the third additional transistor between the first and second power supply voltage terminals. The control signal generation circuit may include a conductive path that connects a first node between the first and second additional transistors to a second node between the third and fourth additional transistors. The first set of transistors may include a fifth additional transistor coupled in series with the first and second additional transistors between the first and second power supply voltage terminals.

If desired, the control signal generation circuit may include a third set of transistors that is interposed between the first and second power supply voltage terminals. The first set of transistors may include a first additional transistor having a gate terminal coupled to the gate terminal of the transistor in the second amplifier stage. The second set of transistors may include a second additional transistor having a gate terminal. The third set of transistors may include a third additional transistor having a gate terminal. The gate terminal of the second additional transistor may be coupled to the gate terminal of the third additional transistor. The first set of transistors may include a fourth additional transistor configured to receive a control signal. The second set of transistors may include a fifth additional transistor configured to receive the control signal. The third set of transistors may include a sixth additional transistor configured to receive the control signal.

As another example, an object detection system may include receiver circuitry, baseband circuitry coupled to the receiver circuitry, and analog-to-digital converter circuitry interposed between the receiver circuitry and the baseband circuitry. The analog-to-digital converter circuitry may include a multiplying digital-to-analog converter stage having a sampling network and amplifier circuitry having an input terminal coupled to the sampling network. The amplifier circuitry may include a transistor coupled between a power supply voltage terminal and an output terminal. The analog-to-digital converter circuitry may also include a control signal generation circuit having an adaptive circuit configured to compensate for changes in a voltage supplied by the power supply voltage terminal. The control signal generation circuit may be configured to generate a control signal for the transistor based on the changes in the voltage supplied by the power supply voltage.

If desired, the control signal generation circuit may include a first additional transistor having a source-drain terminal coupled to a gate terminal of the transistor. The first additional transistor may have a gate terminal that is coupled to the source-drain terminal of the first additional transistor and that is coupled to the gate terminal of the transistor. The adaptive circuit may include a second additional transistor configured to generate a bias current. The first additional transistor may be configured to generate an additional bias current based on the bias current generated by the second additional transistor. The adaptive circuit may include a third additional transistor having a gate terminal that is coupled to a gate terminal of the second additional transistor. The first, second, and third additional transistors may be coupled along first, second, and third respective paths between the power supply voltage terminal and an additional power supply voltage terminal.

As yet another example, a system may include analog circuitry, digital circuitry, and analog-to-digital converter circuitry connecting the analog circuitry to the digital circuitry. The analog-to-digital converter circuitry may include amplifier circuitry having a transistor coupled between a power supply voltage terminal providing a supply voltage and an output terminal of the amplifier circuitry, the transistor having a gate terminal configured to receive a control signal, and may include adaptive control signal generation circuitry configured to generate the control signal based on the supply voltage.

If desired, the amplifier circuitry may include an additional transistor coupled between the power supply voltage terminal and an additional output terminal of the amplifier circuitry, the additional transistor having a gate terminal configured to receive the control signal.

The foregoing is merely illustrative of the principles of this invention and various modifications can be made by those skilled in the art. The foregoing embodiments may be implemented individually or in any combination.

What is claimed is:

1. Amplifier circuitry comprising:
a first amplifier stage having a pair of input terminals for the amplifier circuitry;
a second amplifier stage having a pair of output terminals for the amplifier circuitry and a transistor having a gate terminal;
a first power supply voltage terminal;
a second power supply voltage terminal, wherein the transistor is interposed between the second power supply voltage terminal and a given output terminal in the pair of output terminals; and
a control signal generation circuit coupled to the gate terminal of the transistor, the control signal generation circuit having a first set of transistors that is between the first and second power supply voltage terminals and that is coupled to the gate terminal of the transistor, and the control signal generation circuit having a second set of transistors that is between the first and second power voltage terminals and that is coupled to the first set of transistors.

2. The amplifier circuitry defined in claim 1, wherein the first set of transistors comprises a first additional transistor having a gate terminal coupled to the gate terminal of the transistor in the second amplifier stage.

3. The amplifier circuitry defined in claim 2, wherein the first set of transistors comprises a second additional transistor coupled in series with the first additional transistor between the first and second power supply voltage terminals.

4. The amplifier circuitry defined in claim 3, wherein the second set of transistors comprises a third additional transistor configured to mimic the transistor in the second amplifier stage.

5. The amplifier circuitry defined in claim 4, wherein the second set of transistors comprises a fourth additional transistor coupled in series with the third additional transistor between the first and second power supply voltage terminals.

6. The amplifier circuitry defined in claim 5, wherein the control signal generation circuit includes a conductive path that connects a first node between the first and second additional transistors to a second node between the third and fourth additional transistors.

7. The amplifier circuitry defined in claim 6, wherein the first set of transistors comprises a fifth additional transistor coupled in series with the first and second additional transistors between the first and second power supply voltage terminals.

8. The amplifier circuitry defined in claim 1, wherein the control signal generation circuit includes a third set of transistors that is interposed between the first and second power supply voltage terminals.

9. The amplifier circuitry defined in claim 8, wherein the first set of transistors includes a first additional transistor having a gate terminal coupled to the gate terminal of the transistor in the second amplifier stage.

10. The amplifier circuitry defined in claim 9, wherein the second set of transistors includes a second additional transistor having a gate terminal, the third set of transistors includes a third additional transistor having a gate terminal, and the gate terminal of the second additional transistor is coupled to the gate terminal of the third additional transistor.

11. The amplifier circuitry defined in claim 10, wherein the first set of transistors includes a fourth additional transistor configured to receive a control signal, and the second set of transistors includes a fifth additional transistor configured to receive the control signal.

12. The amplifier circuitry defined in claim 11, wherein the third set of transistors includes a sixth additional transistor configured to receive the control signal.

13. An object detection system comprising:
receiver circuitry;
baseband circuitry coupled to the receiver circuitry and
analog-to-digital converter circuitry interposed between the receiver circuitry and the baseband circuitry, the analog-to-digital converter circuitry comprising:
a multiplying digital-to-analog converter stage having a sampling network and amplifier circuitry having an input terminal coupled to the sampling network, wherein the amplifier circuitry includes a transistor coupled between a power supply voltage terminal and an output terminal; and
a control signal generation circuit having an adaptive circuit configured to compensate for changes in a voltage supplied by the power supply voltage terminal, the control signal generation circuit configured to generate a control signal for the transistor based on the changes in the voltage supplied by the power supply voltage.

14. The object detection system defined in claim 13, wherein the control signal generation circuit comprises a first additional transistor having a source-drain terminal coupled to a gate terminal of the transistor.

15. The object detection system defined in claim 14, wherein the first additional transistor has a gate terminal that is coupled to the source-drain terminal of the first additional transistor and that is coupled to the gate terminal of the transistor.

16. The object detection system defined in claim 15, wherein the adaptive circuit includes a second additional transistor configured to generate a bias current, and the first additional transistor is configured to generate an additional bias current based on the bias current generated by the second additional transistor.

17. The object detection system defined in claim 16, wherein the adaptive circuit includes a third additional transistor having a gate terminal that is coupled to a gate terminal of the second additional transistor.

18. The object detection system defined in claim 17, wherein the first, second, and third additional transistors are coupled along first, second, and third respective paths between the power supply voltage terminal and an additional power supply voltage terminal.

19. A system comprising:
analog circuitry;
digital circuitry; and
analog-to-digital converter circuitry connecting the analog circuitry to the digital circuitry, the analog-to-digital converter circuitry comprising:
amplifier circuitry having a transistor coupled between a power supply voltage terminal providing a supply voltage and an output terminal of the amplifier circuitry, the transistor having a gate terminal configured to receive a control signal; and
adaptive control signal generation circuitry configured to generate the control signal based on the supply voltage.

20. The system defined in claim 19, wherein the amplifier circuitry comprises an additional transistor coupled between the power supply voltage terminal and an additional output terminal of the amplifier circuitry, the additional transistor having a gate terminal configured to receive the control signal.
